(19) United States
(12) Patent Application Publication
(10) Pub. No.: US 2009/0042113 A1
(43) Pub. Date: Feb. 12, 2009

(54) MANUFACTURING METHOD OF FILTER AND COLOR FILTER

(75) Inventors: Yong-Mao Lin, Hsinchu (TW); Wen-Lung Chen, Hsinchu (TW); Yung-Lung Lin, Hsinchu (TW); Fu-Chuan Tsai, Hsinchu (TW); Wei-Ya Wang, Hsinchu (TW); Chun-Chieh Tsao, Hsinchu (TW); Shu-Chin Lee, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Au Optronics Corporation, Hsinchu (TW)

(21) Appl. No.: 12/040,922

(22) Filed: Mar. 3, 2008

(30) Foreign Application Priority Data
Aug. 10, 2007 (TW) 96129599

(51) Int. Cl. G03F 7/16

(52) U.S. Cl. 430/7

(57) ABSTRACT

A manufacturing method of a filter is provided. The manufacturing method includes steps as follows. First, a substrate is provided and a black matrix is formed on the substrate. The black matrix has a number of openings arranged in array. Next, a filter material is individually formed in the openings by inkjet printing or other methods, and the filter material includes a solvent and a dye mixed with the solvent. Thereafter, a thermal treatment is performed and an evaporation rate of the solvent during the thermal treatment is reduced, so as to cure the filter material. As the evaporation rate of the solvent is relatively slow, the filter material is still flowable during the thermal treatment. Hence, the cured filter material has a flat surface. The filter fabricated by the above manufacturing method has an even hue and a well flattened surface.

### CROSS-REFERENCE TO RELATED APPLICATION

This application claims the priority benefit of Taiwan application serial no. 96129599, filed on Aug. 10, 2007. The entirety the above-mentioned patent application is hereby incorporated by reference herein and made a part of specification.

### BACKGROUND OF THE INVENTION

1. Field of the Invention

The present invention relates to a manufacturing method of a filter, and more particularly, to a manufacturing method of a color filter. The manufacturing method is capable of improving thickness uniformity of the color filter fabricated thereby.

2. Description of Related Art

A full color display of a liquid crystal display (LCD) is generally achieved by a disposition of a color filter. Recently, a method for forming the color filter by implementing an inkjet printing process has been developed. In the method, a black matrix is firstly formed on a substrate. The black matrix has a plurality of openings. Next, the inkjet printing process is implemented to inject a filter material (red, green, blue, or the like) individually into the openings of the black matrix. Thereafter, a thermal treatment is performed through implementing a baking process or a heating process using a hot plate, so as to dry and cure the filter material.

Through the inkjet printing technology, the filter material can be directly coated onto the substrate, such that the color filter is fabricated. The inkjet printing technology is predominant because the color filter fabricated thereby requires neither masks nor stencils. By adopting the inkjet printing technology, the manufacturing process of the color filter is simplified, and other issues do not arise due to utilization of other acid solutions and alkaline solutions.

FIG. 1 is a schematic cross-sectional view illustrating a color filter manufactured through performing a conventional inkjet printing process. Referring to FIG. 1, a conventional color filter 100 includes a substrate 110 and a black matrix 120 disposed thereon. The black matrix 120 has a plurality of openings P, and a filter material 130 is individually filled into the openings P. Note that the filter material 130 is filled into the openings P through implementing the inkjet printing process.

When the filter material 130 is filled into the openings P, a wet surface of a color ink generated by performing the inkjet printing process is often at a level higher than the black matrix, such that the filter material 130 is adapted to overflow, giving rise to an intermixture of the filter material 130. Hence, a hydrophobic treatment is usually performed on the black matrix 120 to increase a surface tension of the filter material 130 on the black matrix 120 and to prevent the intermixture of the filter material 130. Nevertheless, as indicated in FIG. 1, it is likely for the dried filter material 130 to have unfavorable thickness uniformity due to the surface tension. In other words, the filter material 130 may be protruding to be convex in the middle but lower at the peripheries. As a surface of the color filter 100 is not flattened, a step coverage of subsequently formed film layers is relatively undesirable, and thus an over coat is required to be disposed on the black matrix 120 and the filter material 130, so as to improve the step coverage of the subsequently formed film layers. On the other hand, as the color filter 100 is applied to the LCD, non-uniformity in thickness of the filter material 130 may result in mura defects in displaying. Accordingly, thickness uniformity of the dried filter material 130 is always taken into great consideration during the fabrication of the color filter 100.

### SUMMARY OF THE INVENTION

The present invention is directed to a manufacturing method of a filter, such that an issue regarding unfavorable thickness uniformity of a filter material in a color filter may be resolved.

The present invention provides a manufacturing method of a filter. The method includes steps as follows. First, a substrate is provided and a black matrix is formed on the substrate. The black matrix has a plurality of openings arranged in array. Next, a filter material is individually formed in the openings, and the filter material includes a solvent and a dye mixed with the solvent. Thereafter, a thermal treatment is performed and an evaporation rate of the solvent during the thermal treatment is reduced, so as to cure the filter material.

According to an embodiment of the present invention, the thermal treatment is carried out by performing a pre-baking process on the filter material at first, for example, so as to shape the filter material. Next, a post-baking process is performed on the filter material to cure the same. Here, the pre-baking process is performed under a pressure (e.g. 1˜5 atm) higher than the normal atmospheric pressure. By contrast, the post-baking process may be implemented under the normal atmospheric pressure, the pressure higher than the normal atmospheric pressure, or the pressure lower than the normal atmospheric pressure. Additionally, a process temperature at which the pre-baking process is performed ranges from 80° C. to 120° C., preferably at 90° C., for example. In comparison, a process temperature at which the post-baking process is performed ranges from 190° C. to 250° C., preferably at 230° C., for example.

According to an embodiment of the present invention, the pre-baking process is carried out in a chamber, and a gas introduced into the chamber includes a gaseous compound of the solvent or a gas which does not react with the filter material. For example, the gas introduced into the chamber includes air, nitrogen, an inert gas, and a combination thereof.

According to an embodiment of the present invention, the solvent includes propylene glycol monomethyl ether acetate (PGMEA).

According to an embodiment of the present invention, the filter material may be formed by performing an inkjet printing process.

According to an embodiment of the present invention, a hydrophobic treatment is further performed on the black matrix after the black matrix is formed on the substrate. Here, the hydrophobic treatment includes a plasma process.

According to an embodiment of the present invention, the cured filter material has a flat surface.

The present invention further provides a manufacturing method of a color filter. In the method, a substrate is provided at first. Next, a black matrix is formed on the substrate. The black matrix has a plurality of first openings, second openings, and third openings. Here, the first openings, the second openings, and the third openings are arranged in array. Thereafter, a first filter material, a second filter material, and a third filter material are formed in the first openings, the second openings, and the third openings, respectively. In addition, the first filter material, the second filter material, and the third filter material include a solvent and a dye. After that, a thermal treatment is performed and an evaporation rate of the solvent during the thermal treatment is reduced under control, so as to cure the first filter material, the second filter material, and the third filter material.

According to an embodiment of the present invention, the first filter material, the second filter material, and the third filter material include a blue filter material, a green filter material, and a red filter material.

According to an embodiment of the present invention, the thermal treatment may be performed under a pressure higher than a normal atmospheric pressure.

According to an embodiment of the present invention, the cured first filter material, the cured second filter material, and the cured third filter material all have flat surfaces.

In accordance with the present invention, during the implementation of the pre-baking process for shaping the filter material, the filter material is still flowable while being cured by virtue of the fact that the evaporation rate of the solvent in the filter material is reduced under the pressure higher than the normal atmospheric pressure or under other conditions. As such, the cured filter material has the well flattened surface and desired thickness uniformity.

In order to make the above and other objects, features and advantages of the present invention more comprehensible, several embodiments accompanied with figures are described in detail below.

### BRIEF DESCRIPTION OF THE DRAWINGS

FIG. 1 is a schematic cross-sectional view illustrating a color filter manufactured through performing a conventional inkjet printing process.

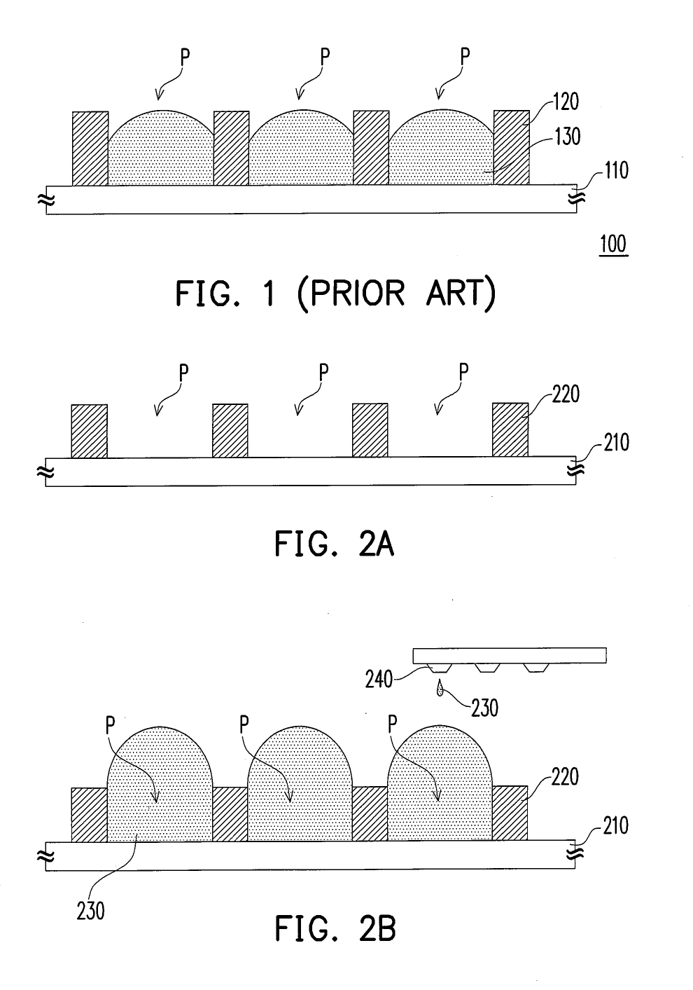

FIGS. 2A through 2D illustrate a manufacturing method of a color filter according to an embodiment of the present invention.

### DESCRIPTION OF EMBODIMENTS

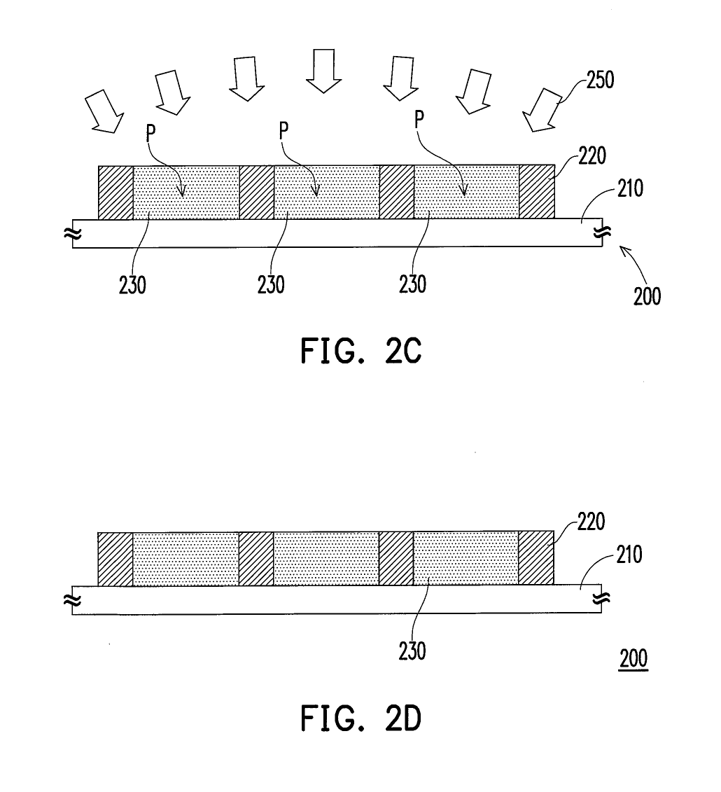

FIGS. 2A through 2D illustrate a manufacturing method of a filter according to an embodiment of the present invention. The manufacturing method of the filter according to the present embodiment includes steps as follows. First, referring to FIG. 2A, a substrate 210 is provided, and then a black matrix 220 is formed on the substrate 210. The black matrix 220 has a plurality of openings P arranged in array. Here, the black matrix 220 is, for example, a resin black matrix or a metal black matrix.

After the black matrix 220 is formed, a hydrophobic treatment may be performed on a surface of the black matrix 220, for example, so as to avoid an overflow of a filter material in subsequent manufacturing processes. In general, the hydrophobic treatment is implemented by performing a plasma process so as to form hydrophobic substances on the surface of the black matrix 220, for example.

Next, referring to FIG. 2B, a filter material 230 is individually formed in the openings P of the black matrix 220. In the present embodiment, the filter material 230 may be formed by implementing an inkjet printing process, so as to fill the filter material 230 into the openings P through a nozzle 240. Specifically, the filter material 230 includes a solvent and a dye mixed with the solvent. The solvent is, for example, PGMEA or other similar solvents, while the dye may have different colors, such as red, green, blue, and so on.

Since the hydrophobic treatment is performed on the surface of the black matrix 220, a tension between the filter material 230 and the surface of the black matrix 220 is significant when the filter material 230 is filled into the openings P. Hence, it is rather unlikely for the colored filter material 230 to overflow, thus preventing an intermixture of the filter material 230 of different colors. However, after the hydrophobic treatment is performed on the black matrix 220, the filter material 230 may have a non-uniform surface protruding in the middle but concave at the peripheries (as depicted in FIG. 2B).

A thermal treatment is then carried out and an evaporation rate of the solvent during the implementation of the thermal treatment is reduced. Referring to FIG. 2C, the thermal treatment is implemented by, for example, performing a pre-baking process 250 on the filter material 230 to shape the same. Note that the pre-baking process 250 is performed under a pressure (e.g. 1˜5 atm) higher than a normal atmospheric pressure, for example. Besides, a process temperature at which the pre-baking process 250 is performed ranges from 80° C. to 120° C., preferably at approximately 90° C., for example.

In an embodiment of the present invention, the pre-baking process 250 may be implemented in a chamber. To increase a pressure in the chamber, a gas may be introduced into the chamber, such that the pressure therein is higher than the normal atmospheric pressure. The gas introduced into the chamber may be a gaseous compound of the solvent or a gas which does not react with the filter material 230. In detail, the gas introduced into the chamber according to the present embodiment may be PGMEA, air, nitrogen, an inert gas, and so forth. In the present invention, the gas which does not react with the filter material 230 may be introduced into the chamber, so as to increase a total pressure therein. In an alternative, the gaseous compound of the solvent may also be introduced to raise a gas partial pressure in the chamber. Through the above, the evaporation rate of the solvent can be reduced.

As the pre-baking process 250 is carried out in the gas-containing chamber, a gas pressure applied to the filter material 230 may reduce the evaporation rate of the solvent. The larger the gas pressure, the slower the evaporation rate of the solvent. In particular, before the filter material 230 is completely shaped, the evaporation rate of the solvent is slower than that under the normal atmospheric pressure, such that the filter material 230 is still flowable. Hence, after the filter material 230 is shaped, the well flattened surface may be obtained, and the favorable thickness uniformity may be accomplished (as indicated in FIG. 2C).

Moreover, the thermal treatment further includes performing a post-baking process (not shown) on the filter material 230 after the implementation of the pre-baking process 250, so as to completely dry and cure the filter material 230 and to form a filter 200. In the pre-baking process 250, a shape of the filter material 230 is fixed. Thus, an outlook of the filter material 230 and flatness thereof are not affected no matter the pressure of the post-baking process is high or low. Consequently, the post-baking process may be performed under the normal atmospheric pressure, the pressure higher than the normal atmospheric pressure, or the pressure lower than the normal atmospheric pressure. In addition, a process temperature at which the post-baking process (not shown) is performed ranges from 190° C. to 250° C., preferably at approximately 230° C., for example. Thereby, the solvent is evaporated, and the filter 200 is then formed (as shown in FIG. 2D).

The above method may also be applied to fabricate a color filter in other embodiments. Here, the openings P of the black matrix 220 may be a plurality of first openings, second openings, and third openings. The first openings, the second openings, and the third openings are all arranged in array. As the openings P of the black matrix 220 are the first openings, the second openings, and the third openings all arranged in array, a first filter material, a second filter material, and a third filter material may be formed in each of the corresponding openings. The first filter material, the second filter material, and the third filter material may be a blue filter material, a green filter material, and a red filter material. Besides, when the first, the second, and the third filter materials are cured, the thermal treatment is implemented under the pressure (e.g. 1˜5 atm) higher than the normal atmospheric pressure, for example, such that the first, the second, and the third filter materials may have flat surfaces after being cured.

In general, as the filter 200 is formed by performing the inkjet printing process, it is imperative to select an appropriate solvent in the filter material 230. For example, given that a certain material having a low boiling point is utilized as the solvent, the evaporation rate of the solvent is relatively fast. Thus, a temperature at which the filter material 230 can be dried is comparatively low, while less time is spent on drying the filter material 230. However, if a large-sized color filter is intended to be formed, the filter material 230 is required to be filled into the openings P for a number of times. As such, parts of the filter material 230 filled into the openings P at an early stage may be dried before the thermal treatment is implemented, causing difficulties in controlling the manufacturing process. To resolve said issue, a plurality of multi-head nozzles can be employed at the same time, so as to shorten the time period during which the filter material 230 is filled into the openings P. Nevertheless, utilization of the multi-head nozzles gives rise to an increase in the manufacturing costs.

On the contrary, given that a certain material having a high boiling point is adopted as the solvent, the evaporation rate of the solvent is relatively slow. Thereby, the filter material may not be partially dried before the thermal treatment is carried out. Hence, it is not necessary to employ the expensive multi-head nozzles, bringing down the manufacturing costs. It should be noted that the comparatively slow evaporation rate of the solvent allows the filter 200 to have the well flattened surface according to the present embodiment of the invention. Based on the above, it is preferably to utilize the material having the high boiling point as the solvent in the filter material 230, so as to fabricate the filter 200 having the flattened surface. For example, the boiling point of PGMEA is approximately at 145° C.˜146° C. Thus, PGMEA is categorized into the material having the high boiling point and may be used as the solvent in the present embodiment.

In light of the foregoing, during the fabrication of the color filter proposed in the present invention, the evaporation rate of the solvent is reduced because of the pressure when the filter material is shaped. Thereby, the dried filter material has the well flattened surface and favorable thickness uniformity. As such, mura defects do not occur when the color filter is applied to the LCD. Furthermore, flatness of the color filter fabricated by performing the manufacturing method of the present invention is desirable, and thus no over coat is required in the subsequent process of forming the film layers. Thereby, the manufacturing costs are reduced, and the manufacturing process is simplified as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a filter, the manufacturing method comprising:
providing a substrate;
forming a black matrix on the substrate, wherein the black matrix has a plurality of openings arranged in array;
forming a filter material individually in the openings, the filter material comprising a solvent and a dye; and
performing a thermal treatment and reducing an evaporation rate of the solvent during the thermal treatment, so as to cure the filter material.

2. The manufacturing method of claim 1, wherein the step of performing the thermal treatment includes:
performing a pre-baking process on the filter material to shape the filter material; and
performing a post-baking process on the filter material to cure the filter material.

3. The manufacturing method of claim 2, wherein the pre-baking process is performed under a pressure higher than a normal atmospheric pressure.

4. The manufacturing method of claim 3, wherein the post-baking process is performed under the normal atmospheric pressure.

5. The manufacturing method of claim 3, wherein the post-baking process is performed under the pressure higher than the normal atmospheric pressure.

6. The manufacturing method of claim 3, wherein the post-baking process is performed under a pressure lower than the normal atmospheric pressure.

7. The manufacturing method of claim 2, wherein the pre-baking process is performed at a process temperature ranging from 80° C. to 120° C.

8. The manufacturing method of claim 2, wherein the pre-baking process is performed at a 90° C. process temperature.

9. The manufacturing method of claim 2, wherein the post-baking process is performed at a process temperature ranging from 190° C. to 250° C.

10. The manufacturing method of claim 2, wherein the post-baking process is performed at a 230° C. process temperature.

11. The manufacturing method of claim 2, wherein the pre-baking process is performed in a chamber.

12. The manufacturing method of claim 11, wherein a gas introduced into the chamber includes a gaseous compound of the solvent.

13. The manufacturing method of claim 11, wherein a gas introduced into the chamber includes a gas which does not react with the filter material.

14. The manufacturing method of claim 11, wherein a gas introduced into the chamber includes air, nitrogen, an inert gas, and a combination thereof.

15. The manufacturing method of claim 1, wherein the solvent includes propylene glycol monomethyl ether acetate (PGMEA).

16. The manufacturing method of claim 1, wherein the step of forming the filter material includes performing an inkjet printing process.

17. The manufacturing method of claim 1, further comprising performing a hydrophobic treatment on the black matrix after the black matrix is formed on the substrate.

18. The manufacturing method of claim 17, wherein the hydrophobic treatment includes a plasma process.

19. The manufacturing method of claim 1, wherein the filter material has a flat surface after the filter material is cured.

20. A manufacturing method of a color filter, the manufacturing method comprising:
providing a substrate;
forming a black matrix on the substrate, wherein the black matrix has a plurality of first openings, second openings, and third openings which are arranged in array;
forming a first filter material, a second filter material, and a third filter material in the first openings, the second openings, and the third openings, respectively, wherein the first filter material, the second filter material, and the third filter material include a solvent and a dye; and
performing a thermal treatment and reducing an evaporation rate of the solvent during the thermal treatment, so as to cure the first filter material, the second filter material, and the third filter material.

21. The manufacturing method of claim 20, wherein the first filter material, the second filter material, and the third filter material include a blue filter material, a green filter material, and a red filter material.

22. The manufacturing method of claim 20, wherein the thermal treatment is performed under a pressure higher than a normal atmospheric pressure.

23. The manufacturing method of claim 20, wherein the first filter material, the second filter material, and the third filter material all have flat surfaces after the first, the second, and the third filter materials are cured.
